(19) United States
(12) Patent Application Publication
(10) Pub. No.: US 2025/0287771 A1
(43) Pub. Date: Sep. 11, 2025

(54) CELL MODULE AND PREPARATION METHOD THEREFOR, AND SOLAR CELL SYSTEM

(71) Applicant: Jiangsu Huixian Display Technology Co., Ltd., Kunshan (CN)

(72) Inventors: Wei GAO, Kunshan (CN); Shengzhi DONG, Kunshan (CN)

(73) Assignee: Jiangsu Huixian Display Technology Co., Ltd., Kunshan (CN)

(21) Appl. No.: 19/218,347

(22) Filed: May 25, 2025

(30) Foreign Application Priority Data
May 29, 2024 (CN) 202410684192.6

(51) Int. Cl. H10K 30/88; H10K 30/40

(52) U.S. Cl. CPC H10K 30/88; H10K 30/40

(57) ABSTRACT

The present application provides a cell module and a preparation method therefor, and a solar cell system. The cell module includes: a substrate; at least one cell located on one side of the substrate; a bend-resistant cladding layer located on a side of the cell away from the substrate, an orthographic projection of the bend-resistant cladding layer on the substrate at least partially overlapping with an orthographic projection of the cell on the substrate; and an encapsulation layer located on the side of the cell away from the substrate and sealingly connected to the substrate.

### CROSS-REFERENCE TO RELATED APPLICATIONS

The present application claims priority to the Chinese Patent Application No. 202410684192.6, filed on May 29, 2024, and the entire contents of the aforementioned application are hereby incorporated by reference in its entirety.

### FIELD

The present application relates to the field of energy storage, and in particular to a cell module and a preparation method therefor, and a solar cell system.

### BACKGROUND

Solar cell systems, such as perovskite solar cell systems, are a very promising photovoltaic technology with relatively low production costs and high power conversion efficiency (PCE). However, there are still some problems that greatly limit the overall encapsulation effect.

### SUMMARY

In view of this, embodiments of the present application provide a cell module. The cell module can be effectively insulated from water and oxygen, and the influence of external forces on the cell module can also be reduced, thereby prolonging the service life of the cell module and therefore the service life of a solar cell system including the cell module.

One embodiment of the present application provides a cell module, including:
a substrate;
at least one cell located on one side of the substrate;
a bend-resistant cladding layer located on a side of the cell away from the substrate, an orthographic projection of the bend-resistant cladding layer on the substrate at least partially overlapping with an orthographic projection of the cell on the substrate; and
an encapsulation layer located on the side of the cell away from the substrate and sealingly connected to the substrate.

One embodiment of the present application provides a preparation method for the cell module as described above, the preparation method including:
providing a substrate;
preparing at least one cell on one side of the substrate;
preparing a bend-resistant cladding layer on a side of the cell away from the substrate,
and an orthographic projection of the bend-resistant cladding layer on the substrate at least partially overlaps with an orthographic projection of the cell on the substrate; and
preparing an encapsulation layer on the side of the cell away from the substrate, and sealingly connecting the encapsulation layer to the substrate.

One embodiment of the present application provides a solar cell system including the cell module as described above, or a cell module prepared by the preparation method as described above.

The provision of the bend-resistant cladding layer on the side of the cell away from the substrate can enable effective insulation from water and oxygen and excellent corrosion resistance. Moreover, the bend-resistant cladding layer can effectively prevent unnecessary bending of the cell module due to the effect of external forces, and the bend-resistant cladding layer can provide a support force or a counter-support force during bending of the cell module, thereby effectively avoiding the problem of latent cracking of the cell, further avoiding intrusion of water and oxygen into the interior of the cell, and further improving the corrosion resistance of the cell module. The cell module of the embodiments of the present application has a prolonged service life and an excellent stability, and a high cell efficiency can be maintained during long-term use.

### BRIEF DESCRIPTION OF THE DRAWINGS

FIG. 1 is a partial structural schematic view of a cell module in one embodiment of the present application.

FIG. 2 is a partial structural schematic view of a cell module in another embodiment of the present application.

FIG. 3 is a structural schematic view of a cell module in another embodiment of the present application.

FIG. 4 is a structural schematic view of a cell module in another embodiment of the present application.

FIG. 5 is a structural schematic view of a cell module in another embodiment of the present application.

FIG. 6 is a structural schematic view of a cell module in another embodiment of the present application.

FIG. 7 is a structural schematic view of a cell module in another embodiment of the present application.

FIG. 8 is a structural schematic view of a cell module in another embodiment of the present application.

FIG. F 9 is a structural schematic view of a cell module in another embodiment of the present application.

FIG. 10 is a structural schematic view of a cell module in another embodiment of the present application.

FIG. 11 is a schematic flow diagram of a preparation method for a cell module in one embodiment of the present application.

FIG. 12 is a schematic flow diagram of a preparation method for a cell module in another embodiment of the present application.

### DETAILED DESCRIPTION OF THE EMBODIMENTS

One embodiment of the present application provides a cell module. With reference to a partial structural schematic view of the cell module shown in FIG. 1, the cell module includes: a substrate 100; at least one cell 200, the cell 200 being located on one side of the substrate 100; a bend-resistant cladding layer 300, the bend-resistant cladding layer 300 being located on a side of the cell 200 away from the substrate, an orthographic projection of the bend-resistant cladding layer 300 on the substrate 100 at least partially overlapping with the orthographic projection of the cell 200 on the substrate 100; and an encapsulation layer 400 located on the side of the cell 200 away from the substrate 100 and sealingly connected to the substrate 100.

The provision of the bend-resistant cladding layer on the side of the cell away from the substrate can enable effective insulation from water and oxygen and excellent corrosion resistance. The bend-resistant cladding layer can also effectively prevent unnecessary bending of the cell module due to the effect of external forces, and the bend-resistant cladding layer can provide a support force or a counter-support force during bending of the cell module, thereby effectively avoiding the problem of latent cracking of the cell, further avoiding intrusion of water and oxygen into the cell, and further improving the corrosion resistance of the cell module. The cell module of the embodiments of the present application has a prolonged service life and an excellent stability, and a high cell efficiency can be maintained during long-term use.

In one embodiment, with reference to the structural schematic view of the cell module shown in FIG. 3, the bend-resistant cladding layer 300 is arranged around the side of the cell 200 away from the substrate 100 and extends into sealing connection with the substrate 100. In this way, the bend-resistant cladding layer and the substrate form a closed cavity in which the cell is located, and the bend-resistant cladding layer is excellent in blocking water and oxygen.

In one embodiment, the bend-resistant cladding layer has a thickness of 50-1000 μm. For example, the thickness may be 50 μm, 100 μm, 200 μm, 300 μm, 400 μm, 500 μm, 600 μm, 700 μm, 800 μm, 900 μm, 1000 μm, etc. In this way, the thickness of the bend-resistant cladding layer is appropriate, the effect of providing support and counter-support is excellent, and unnecessary bending of the cell module can be effectively avoided while ensuring that the cell module has a certain bendability. When the thickness of the bend-resistant cladding layer is less than 50 μm, the bend-resistant cladding layer has a certain effect of resisting unnecessary bending, but the effect of resisting unnecessary bending is not desirable. When the thickness of the bend-resistant cladding layer is greater than 1000 μm, the bendability of the cell is relatively poor, the use effect is relatively poor, and the cost is relatively high.

In one embodiment, a material of the bend-resistant cladding layer includes an Invar alloy or a super Invar alloy. The excellent mechanical properties, low expansion coefficient and high stability of the Invar alloy or the super Invar alloy result in excellent bending resistance of the cell module.

In one embodiment, the Invar alloy includes: a nickel content of 35-37 wt % (e.g., which may be 35 wt %, 35.2 wt %, 35.5 wt %, 35.8 wt %, 36 wt %, 36.2 wt %, 36.4 wt %, 36.6 wt %, 36.8 wt %, 37 wt %, etc.), a carbon content of 0-0.05 wt % (e.g., which may be 0.01 wt %, 0.02 wt %, 0.03 wt %, 0.04 wt %, 0.05 wt %, etc.), a silicon content of 0.2-0.3 wt % (e.g., which may be 0.2 wt %, 0.22 wt %, 0.24 wt %, 0.26 wt %, 0.28 wt %, 0.3 wt %, etc.), a copper content of 0.4-0.8 wt % (e.g., which may be 0.4 wt %, 0.45 wt %, 0.5 wt %, 0.55 wt %, 0.6 wt %, 0.65 wt %, 0.7 wt %, 0.75 wt %, 0.8 wt %, etc.), a manganese content of 0.2-0.6 wt % (e.g., which may be 0.2 wt %, 0.25 wt %, 0.3 wt %, 0.35 wt %, 0.4 wt %, 0.45 wt %, 0.5 wt %, 0.55 wt %, 0.6 wt %, etc.), and an iron content of 61.25-64 wt % (e.g., which may be 61.25 wt %, 61.5 wt %, 62 wt %, 62.5 wt %, 63 wt %, 63.5 wt %, 64 wt %, etc.). In a specific embodiment, the Invar alloy includes: the nickel content of 35-37 wt %, the carbon content of 0-0.05 wt %, the silicon content of 0.2-0.3 wt %, the copper content of 0.4-0.8 wt %, the manganese content of 0.2-0.6 wt %, and the iron content of 61.25-64 wt %. In this way, the Invar alloy has a low thermal expansion coefficient, a high stability and good mechanical properties, and can effectively prevent the problem of the latent cracking of a film layer during bending of an active material layer; and can also make the bend-resistant cladding layer have excellent performance in blocking water and oxygen and resisting corrosion, thereby prolonging the service life of the cell module.

In one embodiment, the Invar alloy includes: nickel 36-37 wt %, carbon 0.01-0.05 wt %, silicon 0.25-0.3 wt %, copper 0.5-0.8 wt %, manganese 0.3-0.6 wt %, and iron 61.25-62.94 wt %.

In a specific embodiment, the Invar alloy includes: nickel 36 wt %, carbon 0.03 wt %, silicon 0.3 wt %, copper 0.6 wt %, manganese 0.4 wt %, and iron 62.67 wt %. In another specific embodiment, the Invar alloy includes: nickel 37 wt %, carbon 0.03 wt %, silicon 0.3 wt %, copper 0.8 wt %, manganese 0.6 wt %, and iron 61.27 wt %.

In one embodiment, the super Invar alloy includes: nickel 31.5-33 wt % (e.g., which may be 31.5 wt %, 31.8 wt %, 32 wt %, 32.2 wt %, 32.4 wt %, 32.6 wt %, 32.8 wt %, 33 wt %, etc.), carbon 0-0.05 wt % (e.g., which may be 0.01 wt %, 0.02 wt %, 0.03 wt %, 0.04 wt %, 0.05 wt %, etc.), silicon 0.2 to 0.3 wt % (e.g., which may be 0.2 wt %, 0.22 wt %, 0.24 wt %, 0.26 wt %, 0.28 wt %, 0.3 wt %, etc.), copper 0.4-0.8 wt % (e.g., which may be 0.4 wt %, 0.45 wt %, 0.5 wt %, 0.55 wt %, 0.6 wt %, 0.65 wt %, 0.7 wt %, 0.75 wt %, 0.8 wt %, etc.), manganese 0.2-0.6 wt % (e.g., which may be 0.2 wt %, 0.25 wt %, 0.3 wt %, 0.35 wt %, 0.4 wt %, 0.45 wt %, 0.5 wt %, 0.55 wt %, 0.6 wt %, etc.), cobalt 3.2-4 wt % (e.g., which may be 3.2 wt %, 3.4 wt %, 3.6 wt %, 3.8 wt %, 4 wt %, etc.), and iron 61.25-64.5 wt % (e.g., which may be 61.25 wt %, 61.5 wt %, 62 wt %, 62.5 wt %, 63 wt %, 63.5 wt %, 64 wt %, 64.5 wt %, etc.). In a specific embodiment, the super Invar alloy includes: nickel 31.5-33 wt %, carbon 0-0.05 wt %, silicon 0.2-0.3 wt %, copper 0.4-0.8 wt %, manganese 0.2-0.6 wt %, cobalt 3.2-4 wt %, and iron 61.5-64.5 wt %. In this way, the super Invar alloy has a lower thermal expansion coefficient, a better toughness, a better resistance to hydrogen brittleness, and better effects of blocking water and oxygen and preventing the latent cracking of the film layer during the bending of the active material layer.

In one embodiment, the super Invar alloy includes: nickel 32-33 wt %, carbon 0.01-0.05 wt %, silicon 0.2-0.25 wt %, copper 0.5-0.8 wt %, manganese 0.3-0.6 wt %, cobalt 3.5-4 wt %, and iron 61.3-63.49 wt %.

In a specific embodiment, the super Invar alloy includes: nickel 32 wt %, carbon 0.01 wt %, silicon 0.2 wt %, copper 0.6 wt %, manganese 0.5 wt %, cobalt 3.5 wt %, and iron 63.19 wt %. In another specific embodiment, the super Invar alloy includes: nickel 33 wt %, carbon 0.05 wt %, silicon 0.2 wt %, copper 0.8 wt %, manganese 0.6 wt %, cobalt 4 wt %, and iron 61.35 wt %.

In the Invar alloy and the super Invar alloy, the content of each component is in mass percentage.

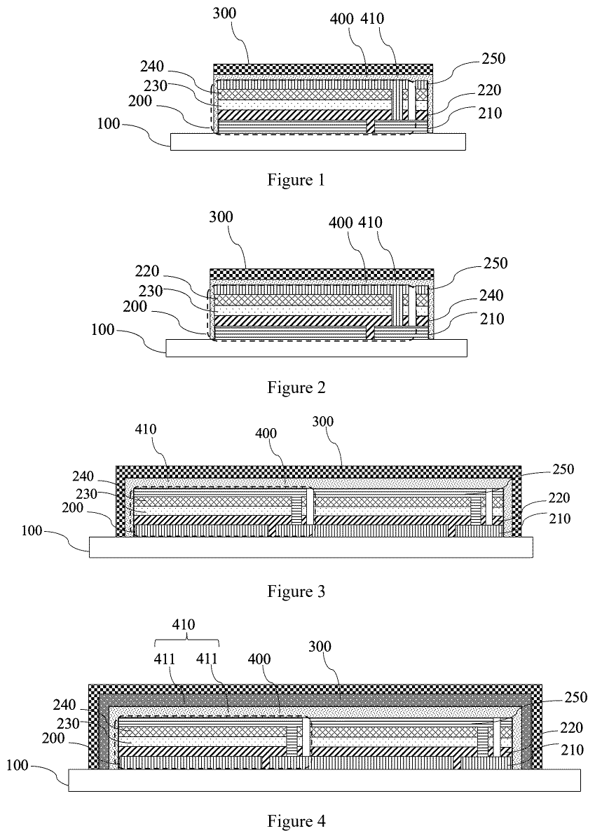

In one embodiment, with reference to the structural schematic view of the cell module shown in FIG. 1, the cell 200 includes a first electrode layer 210, a hole transport layer 220, an active material layer 230, an electron transport layer 240 and a second electrode layer 250 which are sequentially arranged in a stack in a direction perpendicular to the substrate 100. The first electrode layer 210 is located on a side of the hole transport layer 220 close to the substrate 100. In another embodiment, with reference to the partial structural schematic view of the cell module shown in FIG. 2, the cell 200 includes a first electrode layer 210, an electron transport layer 240, an active material layer 230, a hole transport layer 220 and a second electrode layer 250 which are sequentially arranged in a stack in a direction perpendicular to the substrate 100. The first electrode layer 210 is located on a side of the electron transport layer 240 close to the substrate 100. By way of example, the active material layer 230 includes perovskite. The perovskite may be an organic-inorganic hybrid material, which will decompose in a water-oxygen environment. Therefore, the cell has high requirements for blocking water and oxygen. Moreover, the perovskite is relatively soft and bendable, so that the cell module including the perovskite is likely to be bent under external forces. As a result, the cell module is likely to be deformed, and after it is bent many times, the active material layer is prone to latent cracking. The bend-resistant cladding layer 300 in the present application can not only function to excellently block water and oxygen, but can also function to support the cell module to some extent, so that the cell module is bent when deformation is desirable, and provides a support force or a counter-support force for the perovskite during bending. The active material layer 230 is effectively protected, and the latent cracking of the active material layer 230 is prevented.

When the cell module includes a plurality of cells, the plurality of cells may be connected in series in sequence. Specifically, a second electrode layer of a preceding cell is electrically connected to a first electrode layer of a succeeding cell. Current flows from the preceding cell to the succeeding cell.

In a specific embodiment, the first electrode layer includes a transparent electrode, and the substrate includes a light-transmissive flexible substrate. The cell module is a flexible cell module. The first electrode layer, the second electrode layer, the active material layer, the electron transport layer and the hole transport layer are prone to latent cracking due to deformation during a bending-like deformation of the cell module, and the bend-resistant cladding layer can provide a support force or a counter-support force to the above film layers to prevent latent cracking of the film layers, thereby prolonging the service life of the cell module.

By way of example, a material of the light-transmissive flexible substrate includes colorless polyimide (CPI), polyethylene naphthalate (PEN), and polyethylene terephthalate (PET). The flexible substrate is prone to bending, resulting in the entire cell module being prone to bending, so that the cell module is very prone to unnecessary bending under external forces, and the active material layer of the cell module is more prone to latent cracking. The support function of the bend-resistant cladding layer can reduce the occurrence of unnecessary bending of the cell module, effectively prolonging the service life of the cell module. The necessary bending refers to the intended bending of the cell module during use, and the unnecessary bending refers to the bending of the cell module beyond its intended purpose during use.

In one embodiment, the first electrode layer includes at least one of indium tin oxide (ITO), fluorine-doped tin oxide (FTO), and indium-doped zinc oxide (IZO). In this way, the first electrode layer has a strong conductivity and excellent light transmission performance.

In one embodiment, the second electrode layer includes a transparent electrode and/or a metal electrode.

The active material layer, the electron transport layer and the hole transport layer are of conventional materials. By way of example, the material of the electron transport layer includes titanium dioxide, zinc oxide, tin dioxide, etc.; and the material of the hole transport layer includes poly(triarylamine) (PTAA), nickel oxide, copper (I) thiocyanate (CuSCN) or cuprous oxide. By way of example, the material of the active material layer may be MAPbI₃, MAₓFA₁₋ₓPbI₃, (MAₓFA₁₋ₓ)_{y}CS_{1-y}PbI₃, MAPbIₓBr₁₋ₓ, MAₓFA₁₋ₓPbI_{y}Br_{1-y}, (MAₓFA₁₋ₓ)_{y}CS_{1-y}PbI_{Z}Br_{1-Z}, MAPbIₓCl₁₋ₓ, MAₓFA₁₋ₓPbI_{y}Cl_{1-y}, MAPbₓSn₁₋ₓI₃, FAPbₓSn₁₋ₓI₃, CsPbₓSn₁₋ₓI₃, etc., where MA in the above formulae is methylamine (formula CH₃NH₂), FA is formamidine (formula HC(NH₂)₂), and x, y, and z are numbers from 0 to 1.

In one embodiment, with reference to the partial structural schematic view of the cell module shown in FIG. 1, the encapsulation layer 400 includes: a first encapsulation layer 410 located between the cell 200 and the bend-resistant cladding layer 300. In this way, water and oxygen can be further blocked from intruding into the cell, to further improve the corrosion resistance of the cell module, thereby prolonging the service life of the cell module.

In one embodiment, the first encapsulation layer includes at least one of Al₂O₃, ZrO₂, ZnO, TiO₂, SnO₂, SiNx and SiO₂. In this way, the first encapsulation layer is excellent in blocking water and oxygen.

In one embodiment, the first encapsulation layer has a thickness of 100-5000 nm. For example, the thickness may be 100 nm, 500 nm, 1000 nm, 1500 nm, 2000 nm, 2500 nm, 3000 nm, 3500 nm, 4000 nm, 4500 nm, 5000 nm, etc. In this way, the first encapsulation layer is excellent in blocking water and oxygen.

In one embodiment, the first encapsulation layer includes a plurality of first encapsulation sublayers arranged in a stack. In one embodiment, the first encapsulation sublayer in contact with the cell has a thickness of 10 nm to 50 nm. In a specific embodiment, with reference to the structural schematic view of the cell module shown in FIG. 4, the first encapsulation layer 410 includes two first encapsulation sublayers 411 arranged in a stack, the first encapsulation sublayer 411 in contact with the cell having a thickness of 10-50 nm.

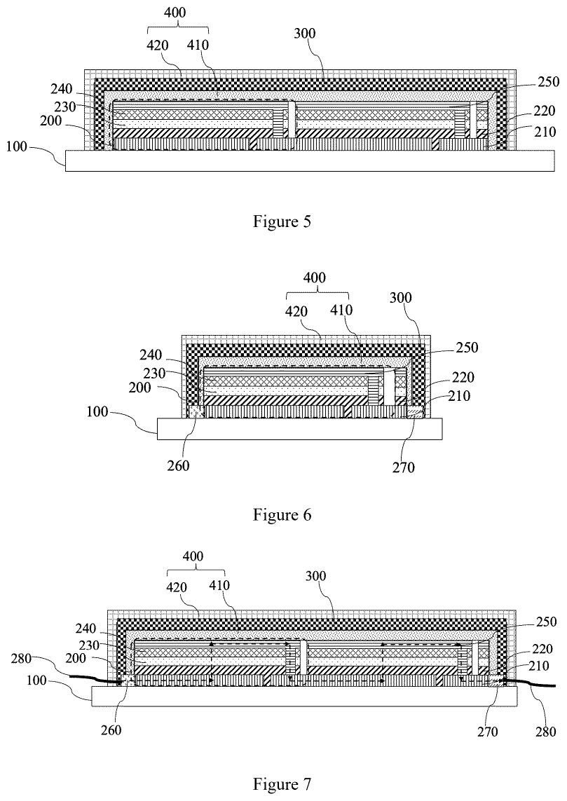

In one embodiment, with reference to the structural schematic view of the cell module shown in FIG. 5, the encapsulation layer further includes a second encapsulation layer 420. The second encapsulation layer 420 is located on a side of the bend-resistant cladding layer 300 away from the substrate 100, and is sealingly connected to the substrate 100. In this way, the second encapsulation layer 420 can also function to block water and oxygen to some extent.

In one embodiment, the second encapsulation layer includes a thermoplastic elastomer. By way of example, the thermoplastic elastomer includes polyethylene terephthalate (polyethylene terephthalate, PET) and/or polyolefin elastomer (POE). In this way, the second encapsulation layer has a better water and oxygen isolation effect and a higher strength, and can effectively protect the cell.

In one embodiment, with reference to the structural schematic views of the cell module shown in FIGS. 6 to 10, the cell 200 further includes: a first current extraction structure 260 and a second current extraction structure 270 which are located on one side of the substrate 100. The first current extraction structure 260 is electrically connected to the first electrode layer 210 of at least one cell 200, and the second current extraction structure 270 is electrically connected to the second electrode layer 250 of at least one cell 200. The first encapsulation layer 410 is arranged around the side of the cell 200 away from the substrate 100, and is sealingly connected to each of the first current extraction structure 260 and the second current extraction structure 270. In this way, the first current extraction structure 260 and the second current extraction structure 270 can respectively lead out the first electrode layer 210 and the second electrode layer 250, avoiding perforations in the cell. The structure is simple, convenient, and easy to implement. The cell module has good airtightness, so that the service life of the cell module is further prolonged.

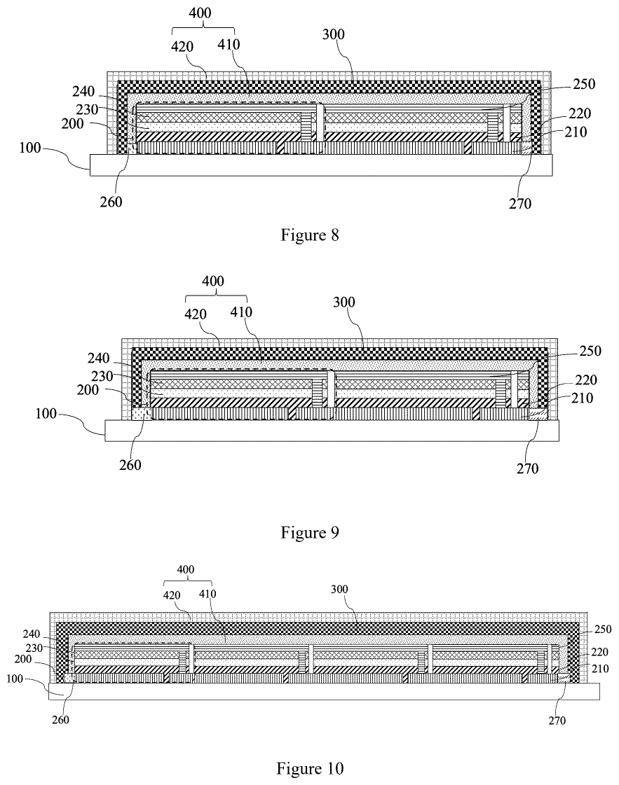

By way of example, in a direction away from the cell 200, an edge of an orthographic projection of the first current extraction structure 260 on the substrate 100 coincides with an edge of an orthographic projection of the first encapsulation layer 410 on the substrate 100 (with particular reference to FIG. 8), or the edge of the orthographic projection of the first current extraction structure 260 on the substrate 100 is located between the edge of the orthographic projection of the first encapsulation layer 410 on the substrate 100 and an edge of an orthographic projection of the bend-resistant cladding layer 300 on the substrate 100 (with particular reference to FIG. 6, 7 or 10), or the edge of the orthographic projection of the first current extraction structure 260 on the substrate 100 coincides with the edge of the orthographic projection of the bend-resistant cladding layer 300 on the substrate 100 (with particular reference to FIG. 9).

By way of example, in a direction away from the cell 200, an edge of an orthographic projection of the second current extraction structure 270 on the substrate 100 coincides with an edge of an orthographic projection of the first encapsulation layer 410 on the substrate 100 (with particular reference to FIG. 8), or the edge of the orthographic projection of the second current extraction structure 270 on the substrate 100 is located between the edge of the orthographic projection of the first encapsulation layer 410 on the substrate 100 and an edge of an orthographic projection of the bend-resistant cladding layer 300 on the substrate 100 (with particular reference to FIG. 6, 7 or 10), or the edge of the orthographic projection of the second current extraction structure 270 on the substrate 100 coincides with the edge of the orthographic projection of the bend-resistant cladding layer 300 on the substrate 100 (with particular reference to FIG. 9). By the bend-resistant cladding layer 300 being arranged around the side of the cell 200 away from the substrate 100 and extending into sealing connection with the substrate 100, it may be meant that the bend-resistant cladding layer 300 is sealingly connected directly to the substrate 100 (with particular reference to FIG. 8), or the bend-resistant cladding layer 300 is sealingly connected to the first current extraction structure 260 and the second current extraction structure 270 arranged on a surface of the substrate 100 (with particular reference to FIG. 9), or the bend-resistant cladding layer 300 is sealingly connected to the substrate 100 and to the first current extraction structure 260 and the second current extraction structure 270 arranged on the surface of the substrate 100 (with particular reference to FIG. 6, 7 or 10).

In one embodiment, a material of the first current extraction structure is as same as the first electrode layer, and a material of the second current extraction structure is as same as the second electrode layer. In this way, the first current extraction structure has the same resistance as the first electrode layer, and the second current extraction structure has the same resistance as the second electrode layer, to ensure a high cell efficiency of the cell. By way of example, the second current extraction structure and the second electrode layer are formed in the same manufacturing process. Specifically, the second current extraction structure and the second electrode layer are formed by evaporation using the same mask.

By way of example, with reference to FIG. 6, the cell module includes one cell, and the first current extraction structure 260 and the second current extraction structure 270 are located in the same layer as the first electrode layer 210, and are respectively at two ends of the first electrode layer 210. With reference to FIGS. 7 to 9, the cell module includes two cells, the first current extraction structure 260 and the second current extraction structure 270 are located in the same layer as the first electrode layer 210, the first current extraction structure 260 is located at one end of the preceding cell 200, the second current extraction structure 270 is located at one end of the succeeding cell 200, and the first current extraction structure 260 and the second current extraction structure 270 are located at opposite ends of the cell module. With reference to FIG. 10, the cell module includes a plurality of cells, the first current extraction structure 260 and the second current extraction structure 270 are located in the same layer as the first electrode layer 210, the first current extraction structure 260 is located at one end of the first one of the cells 200 arranged in sequence, the second current extraction structure 270 is located at one end of the last cell 200, and the first current extraction structure 260 and the second current extraction structure 270 are located at opposite ends of the cell module.

In one embodiment, the solar cell system is a perovskite solar cell system. With reference to the structural schematic view of the cell module shown in FIG. 7, the current flow direction of the cell 200 during operation is shown in dashed lines. The second current extraction structure 270 enables current extraction from the second electrode layer 250, facilitating subsequent testing of the power conversion efficiency (PCE) of the cell module and use of the cell module. In a specific embodiment, with reference to the structural schematic view of the cell module shown in FIG. 7, current in the second current extraction structure 270 and the first current extraction structure 260 is extracted through lead wires 280.

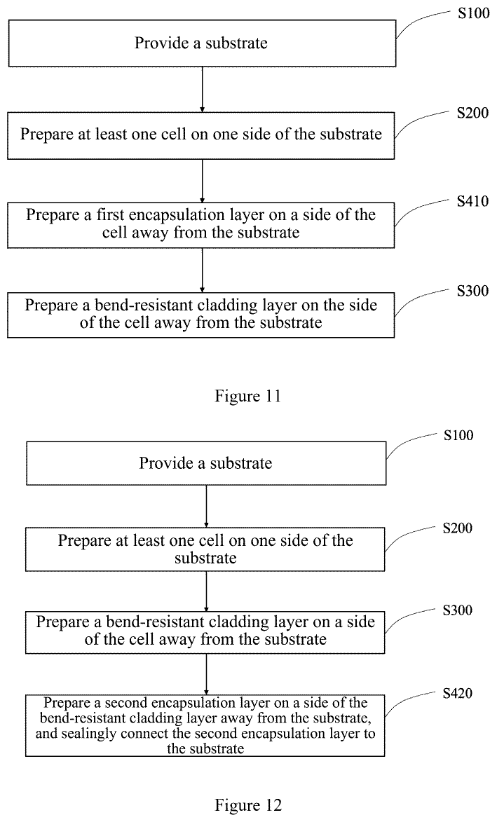

One embodiment of the present application provides a preparation method for the cell module as described above. With reference to the schematic flow diagrams of the preparation method shown in FIGS. 11 and 12, the preparation method for the cell module includes the following steps.

In step S100, a substrate is provided.

The substrate is consistent with the previous description and will not be described in detail here.

In step S200, at least one cell is prepared on one side of the substrate.

The cell is consistent with the previous description and will not be described in detail here.

In a specific embodiment, the cell further includes: a first current extraction structure and a second current extraction structure which are located on one side of the substrate, the first current extraction structure being electrically connected to the first electrode layer of at least one cell, and the second current extraction structure being electrically connected to the second electrode layer of at least one cell. The preparation of at least one cell on one side of the substrate includes: preparing a first electrode layer and a first current extraction structure on one side of the substrate; preparing a hole transport layer, an active material layer and an electron transport layer, which are sequentially arranged in a stack, on a surface of the first electrode layer away from the substrate; and preparing a second electrode layer and a second current extraction structure, the second electrode layer being located on a surface of the electron transport layer away from the substrate, and the second current extraction structure and the first current extraction structure being located on the same side of the substrate; or preparing a first electrode layer and a first current extraction structure on one side of the substrate; preparing an electron transport layer, an active material layer and a hole transport layer, which are sequentially arranged in a stack, on a surface of the first electrode layer away from the substrate; and preparing a second electrode layer and a second current extraction structure, the second electrode layer being located on a surface of the electron transport layer away from the substrate, and the second current extraction structure and the first current extraction structure being located on the same side of the substrate.

By way of example, the second electrode layer and the second current extraction structure are prepared using the same mask.

In step S300, a bend-resistant cladding layer is prepared on a side of the cell away from the substrate.

An orthographic projection of the bend-resistant cladding layer on the substrate at least partially overlaps with an orthographic projection of the cell on the substrate.

The bend-resistant cladding layer is consistent with the previous description and will not be described in detail here.

In one embodiment, the bend-resistant cladding layer is prepared along a side edge of the cell perpendicular to the substrate and along the side of the cell away from the substrate by using an attachment method. In this way, the preparation method is simple, convenient, easy to implement, and the cost is relatively low.

By way of example, the preparation of the bend-resistant cladding layer on the side of the cell away from the substrate using an attachment method includes: preparing the bend-resistant cladding layer by electrostatic attachment without the need for additional film layers such as bonding layers.

During the preparation of the bend-resistant cladding layer, the bend-resistant cladding layer may be sealingly connected to the first current extraction structure and the second current extraction structure.

In one embodiment, the preparation method for the cell module further includes: preparing an encapsulation layer on the side of the cell away from the substrate, and sealingly connecting the encapsulation layer to the substrate.

In one embodiment, the encapsulation layer includes a first encapsulation layer located between the cell and the bend-resistant cladding layer. With reference to the schematic flow diagram of the preparation method shown in FIG. 11, the step of preparing an encapsulation layer on the side of the cell away from the substrate is provided before the preparation of the bend-resistant cladding layer on the side of the cell away from the substrate. The preparation of the encapsulation layer on the side of the cell away from the substrate includes the following step.

In step S410, the first encapsulation layer is prepared on the side of the cell away from the substrate.

The first encapsulation layer is consistent with the previous description and will not be described in detail here.

In one embodiment, the method for preparing a first encapsulation layer on the side of the cell away from the substrate includes: at least one of physical vapor deposition, chemical vapor deposition, and atomic layer deposition. In this way, the above method is simple to operate, convenient, easy to implement, and suitable for large-scale applications. In one embodiment, the method for preparing a first encapsulation layer on the side of the cell away from the substrate includes atomic layer deposition. In this way, the first encapsulation layer formed by the atomic deposition method is denser and has a better effect of isolating water and oxygen.

In one embodiment, the first encapsulation layer includes a plurality of first encapsulation sublayers arranged in a stack, and preparing the first encapsulation layer on the side of the cell away from the substrate includes: preparing the plurality of first encapsulation sublayers arranged in a stack on the side of the cell away from the substrate, where the first encapsulation sublayer in contact with the cell is prepared by atomic layer deposition. In this way, the first encapsulation sublayer is more closely bonded to the cell and is more conducive to isolating water and oxygen.

In one embodiment, the encapsulation layer further includes a second encapsulation layer. The second encapsulation layer is located on a side of the bend-resistant cladding layer away from the substrate, and is sealingly connected to the substrate. With reference to the schematic flow diagram of the preparation method shown in FIG. 12, the preparation of the encapsulation layer on the side of the cell away from the substrate further includes the following step.

In step S420, the second encapsulation layer is prepared on a side of the bend-resistant cladding layer away from the substrate, and the second encapsulation layer is sealingly connected to the substrate.

The method for preparing the second encapsulation layer is the same as the method for preparing a second encapsulation layer of a conventional cell module and will not be described in detail here.

One embodiment of the present application provides a solar cell system including the cell module as described above, or a cell module prepared by the preparation method as described above.

By way of example, the solar cell system is a perovskite solar cell system, which may include, in addition to including the cell module as described above, a structure that a conventional solar cell system should have, such as a housing, which will not be described in detail here.

The present application will be further described below in connection with specific examples.

### Example 1

The structure of the cell module is as follows.

A substrate is made of a CPI material.

A cell is located on a surface of the substrate. The cell includes a first electrode layer, a hole transport layer, an active material layer, an electron transport layer and a second electrode layer which are sequentially arranged in a stack in a direction away from the substrate, the active material layer including perovskite; and a first current extraction structure and a second current extraction structure which are located on one side of the substrate, the first current extraction structure being electrically connected to the first electrode layer of the cell, and the second current extraction structure being electrically connected to the second electrode layer of the cell. A material of the first electrode layer and the first current extraction structure is ITO, and the first electrode layer and the first current extraction structure have a thickness of 200 nm; a material of the hole transport layer is PTAA, and the hole transport layer has a thickness of 25 nm; a material of perovskite is MAPbI3 (MA is methylamine, and MA has the formula CH3NH2), and the active material layer has a thickness of 450 nm; a material of the electron transport layer is titanium dioxide, and the electron transport layer has a thickness of 35 nm; and a material of the second electrode layer and the second current extraction structure is silver, and the second electrode layer and the second current extraction structure have a thickness of 200 nm.

A first encapsulation layer is arranged around a side of the cell away from the substrate, and is sealingly connected to each of the first current extraction structure and the second current extraction structure. A material of the first encapsulation layer is Al2O3, and has a thickness of 100 nm.

A bend-resistant cladding layer is located on the side of the cell away from the substrate and on a surface of the first encapsulation layer away from the substrate. A material of the bend-resistant cladding layer is an Invar alloy including: nickel 37 wt %, carbon 0.05 wt %, silicon 0.3 wt %, copper 0.8 wt %, manganese 0.6 wt %, and iron 61.25 wt %. The bend-resistant cladding layer has a thickness of 50 μm.

A second encapsulation layer is located on a side of the bend-resistant cladding layer away from the cell, and is sealingly connected to the substrate.

### Example 2

The structure of the cell module is basically the same as that of Example 1, except that the bend-resistant cladding layer is bent in a thickness direction of the cell, and is sealingly connected to the substrate.

### Example 3

The structure of the cell module is basically the same as that of Example 2, except that the material of the bend-resistant cladding layer is a super Invar alloy including: nickel 33 wt %, carbon 0.05 wt %, silicon 0.2 wt %, copper 0.8 wt %, manganese 0.6 wt %, cobalt 4 wt %, and iron 59.1 wt %.

### Example 4

The structure of the cell module is basically the same as that of Example 2, except that the bend-resistant cladding layer has a thickness of 1000 μm.

### Example 5

The structure of the cell module is basically the same as that of Example 2, except that the bend-resistant cladding layer has a thickness of 400 μm.

### Example 6

The structure of the cell module is basically the same as that of Example 2, except that the bend-resistant cladding layer has a thickness of 800 μm.

### Example 7

The structure of the cell module is basically the same as that of Example 2, except that the bend-resistant cladding layer has a thickness of 20 μm.

### Example 8

The structure of the cell module is basically the same as that of Example 2, except that the bend-resistant cladding layer has a thickness of 1500 μm.

### Comparative Example 1

The structure of the cell module is basically the same as that of Example 2, except that the material of the bend-resistant cladding layer is an aluminum foil.

### Comparative Example 2

The structure of the cell module is basically the same as that of Example 2, except that no bend-resistant cladding layer is included.

The cell modules of Examples 1 to 8 and Comparative Examples 1 to 2 were bent by a bending angle of 90° using a force of 350 N, and the PCE lost after the cell modules were bent 1000 to 5000 times was measured. The results are shown in Table 1 below.

TABLE 1

| | Number of bends | Lost PCE |
|---|---|---|
| Example 1 | 1000 | 16% |
| Example 2 | 5000 | 14% |
| Example 3 | 5000 | 9% |
| Example 4 | 1000 | 13% |
| Example 5 | 3000 | 11% |
| Example 6 | 1500 | 13% |
| Example 7 | 1000 | 20% |
| Example 8 | 5000 | 13% |
| Comparative Example 1 | 1000 | 30% |
| Comparative Example 2 | 1000 | 50% |

The above description has been given for purposes of illustration and description. Moreover, this description is not intended to limit the embodiments of the present application to the form disclosed herein. While various example aspects and embodiments have been discussed above, certain variations, modifications, alterations, additions and sub-combinations may be made.

What is claimed is:

1. A cell module, comprising:
a substrate;
at least one cell located on one side of the substrate;
a bend-resistant cladding layer located on a side of the cell away from the substrate, an orthographic projection of the bend-resistant cladding layer on the substrate at least partially overlapping with an orthographic projection of the cell on the substrate; and
an encapsulation layer located on the side of the cell away from the substrate and sealingly connected to the substrate.

2. The cell module according to claim 1, wherein the bend-resistant cladding layer is arranged around the side of the cell away from the substrate, and extends into sealing connection with the substrate.

3. The cell module according to claim 1, wherein the bend-resistant cladding layer has a thickness of 50 μm to 1000 μm.

4. The cell module according to claim 1, wherein a material of the bend-resistant cladding layer comprises an Invar alloy or a super Invar alloy.

5. The cell module according to claim 4, wherein the Invar alloy comprises a nickel content of 35-37 wt %, a carbon content of 0-0.05 wt %, a silicon content of 0.2-0.3 wt %, a copper content of 0.4-0.8 wt %, a manganese content of 0.2-0.6 wt %, and an iron content of 61.25-64 wt %; or
the super Invar alloy comprises the nickel content of 31.5-33 wt %, the carbon content of 0-0.05 wt %, the silicon content of 0.2-0.3 wt %, the copper content of 0.4-0.8 wt %, the manganese content of 0.2-0.6 wt %, the cobalt content of 3.2-4 wt %, and the iron content of 61.25-64.5 wt %.

6. The cell module according to claim 4, wherein the Invar alloy comprises a nickel content of 36-37 wt %, a carbon content of 0.01-0.05 wt %, a silicon content of 0.25-0.3 wt %, a copper content of 0.5-0.8 wt %, a manganese content of 0.3-0.6 wt %, and an iron content of 61.25-62.94 wt %; or the super Invar alloy comprises the nickel content of 32-33 wt %, the carbon content of 0.01-0.05 wt %, the silicon content of 0.2-0.25 wt %, the copper content of 0.5-0.8 wt %, the manganese content of 0.3-0.6 wt %, the cobalt content of 3.5-4 wt %, and the iron content of 61.3-63.49 wt %.

7. The cell module according to claim 1, wherein the cell comprises a first electrode layer, a hole transport layer, an active material layer, an electron transport layer and a second electrode layer which are sequentially arranged in a stack in a direction perpendicular to the substrate, wherein the first electrode layer is located on a side of the hole transport layer close to the substrate; or
the cell comprises a first electrode layer, an electron transport layer, an active material layer, a hole transport layer and a second electrode layer which are sequentially arranged in a stack in a direction perpendicular to the substrate, wherein the first electrode layer is located on a side of the electron transport layer close to the substrate.

8. The cell module according to claim 7, wherein the active material layer comprises perovskite; or
the first electrode layer comprises a transparent electrode, and the substrate comprises a light-transmissive flexible substrate.

9. The cell module according to claim 1, wherein the encapsulation layer comprises a first encapsulation layer located between the cell and the bend-resistant cladding layer;
the first encapsulation layer comprises at least one of Al₂O₃, ZrO₂, ZnO, TiO₂, SnO₂, SiNx and SiO₂, and the first encapsulation layer has a thickness of 100 nm to 5000 nm; or
the first encapsulation layer comprises a plurality of first encapsulation sublayers arranged in a stack, the first encapsulation sublayer in contact with the cell having a thickness of 10 nm to 50 nm.

10. The cell module according to claim 1, wherein the cell further comprises a first current extraction structure and a second current extraction structure which are located on one side of the substrate, the first current extraction structure being electrically connected to a first electrode layer of at least one cell, and the second current extraction structure being electrically connected to a second electrode layer of at least one cell; and a first encapsulation layer is arranged around the side of the cell away from the substrate, and is sealingly connected to each of the first current extraction structure and the second current extraction structure.

11. The cell module according to claim 10, wherein a material of the first current extraction structure is as same as a first electrode layer, and a material of the second current extraction structure is as same as a second electrode layer.

12. The cell module according to claim 10, wherein the bend-resistant cladding layer is arranged around the side of the cell away from the substrate, and is sealingly connected to the substrate, or to the first current extraction structure and the second current extraction structure.

13. The cell module according to claim 1, wherein the encapsulation layer further comprises a second encapsulation layer located on a side of the bend-resistant cladding layer away from the substrate and sealingly connected to the substrate; and
the second encapsulation layer comprises a thermoplastic elastomer.

14. A preparation method for a cell module, the preparation method comprising:
providing a substrate;
preparing at least one cell on one side of the substrate;
preparing a bend-resistant cladding layer on a side of the cell away from the substrate,
wherein an orthographic projection of the bend-resistant cladding layer on the substrate at least partially overlaps with an orthographic projection of the cell on the substrate; and
preparing an encapsulation layer on the side of the cell away from the substrate, and sealingly connecting the encapsulation layer to the substrate.

15. The preparation method according to claim 14, wherein preparing a bend-resistant cladding layer on a side of the cell away from the substrate comprises: preparing the bend-resistant cladding layer along a side edge of the cell perpendicular to the substrate and along the side of the cell away from the substrate by using an attachment method.

16. The preparation method according to claim 14, wherein the encapsulation layer comprises a first encapsulation layer, and preparing an encapsulation layer on the side of the cell away from the substrate comprises: preparing the first encapsulation layer on the side of the cell away from the substrate.

17. The preparation method according to claim 16, wherein the method for preparing a first encapsulation layer on the side of the cell away from the substrate comprises: at least one of physical vapor deposition, chemical vapor deposition, and atomic layer deposition.

18. The preparation method according to claim 16, wherein the first encapsulation layer comprises a plurality of first encapsulation sublayers arranged in a stack, and preparing the first encapsulation layer on the side of the cell away from the substrate comprises: preparing the plurality of first encapsulation sublayers arranged in a stack on the side of the cell away from the substrate, wherein the first encapsulation sublayer in contact with the cell is prepared by atomic layer deposition.

19. The preparation method according to claim 14, wherein the encapsulation layer further comprises a second encapsulation layer, and preparing an encapsulation layer on the side of the cell away from the substrate further comprises: preparing the second encapsulation layer on a side of the bend-resistant cladding layer away from the substrate, and sealingly connecting the second encapsulation layer to the substrate.

20. A solar cell system, comprising: a cell module of claim 1; or a cell module prepared by a preparation method of claim 14.
